(19) United States
(12) Patent Application Publication
(10) Pub. No.: US 2026/0163509 A1
(43) Pub. Date: Jun. 11, 2026

(54) Magnetic Flux Density Sensor-Based Smart Electromotive Machine Control System

(71) Applicants: Don Damith Nadishan COLAMBATHANTHRIGE, Western Province (LK); Chitral J ANGAMMANA, Western Province (LK); Jac PRABASH, Western Province (LK)

(72) Inventors: Don Damith Nadishan COLAMBATHANTHRIGE, Western Province (LK); Chitral J ANGAMMANA, Western Province (LK); Jac PRABASH, Western Province (LK)

(73) Assignee: Perpion (PVT) Ltd., Boralasgamuwa (LK)

(21) Appl. No.: 19/412,583

(22) Filed: Dec. 8, 2025

Related U.S. Application Data
(60) Provisional application No. 63/729,727, filed on Dec. 9, 2024.

(51) Int. Cl. H02P 23/14; G01R 31/34; H02K 1/17; H02K 11/20

(52) U.S. Cl. CPC H02P 23/14; G01R 31/343; H02K 1/17; H02K 11/20

(57) ABSTRACT

The present invention discloses a magnetic flux density sensor-based smart electromotive machine control system. This smart electromotive machine control system represents a sophisticated approach to optimizing motor performance by leveraging real-time information about the magnetic flux density within an electromotive machine assembly. The system utilizes magnetic flux density sensors strategically positioned within the assembly to continuously monitor and measure flux levels. It dynamically adjusts and optimizes the operation of the electromagnetic coils of the electromotive machine based on the feedback received from the magnetic flux sensors.

### FIELD OF THE INVENTION

The present invention relates to intelligent electromotive machine control system for controlling an electromotive machine such as motors and generators, and for further optimizing the performance of these machines. More particularly, the present invention relates to an electromotive machine control system that incorporates advanced magnetic flux desnsity sensor-based algorithms and data driven approach to predict and pre-emptively adjust the electromotive machine parameters based on anticipated changes in load or speed requirements, while significantly reducing the energy consumption.

### BACKGROUND OF THE INVENTION

Intelligent Motor Control Systems (IMCS) signify a paradigm shift in industrial motor management, surpassing the limitations of conventional control systems. These sophisticated solutions integrate cutting-edge monitoring and control devices, offering real-time insights into motor operations and taking performance management to unprecedented levels. The key features of IMCS encompass seamless network connectivity for centralized control, predictive maintenance capabilities that proactively anticipate equipment failures, and energy-efficient measures designed to optimize the cost-effectiveness of industrial operations.

In the existing literature, two primary control mechanisms have been extensively explored for regulating electromotive machine operation. One of the control mechanisms is sensor-based control mechanism and other is sensor-less control mechanism. The sensor-based mechanisms constitute a spectrum of sophisticated sensing technologies, including Hall-effect sensors, encoders, Frequency Generating (FG) traces, and resolvers. These cutting-edge sensors play a pivotal role in discerning the exact position of the electromotive machine, thus facilitating precise control over its operation.

Hall-effect sensors, for instance, leverage the Hall-effect phenomenon to detect changes in magnetic fields, providing valuable feedback regarding the motor's position. Encoders, on the other hand, utilize a rotating disc or a strip with alternating light and dark segments to measure the motor's angular position accurately. Similarly, FG traces, through their ability to generate frequency signals proportional to motor movement, offer real-time insights into the motor's rotational position. In parallel, resolvers, with their robust design and ability to withstand harsh environments, provide reliable feedback on the motor's rotational position. Collectively, these sensors form the backbone of sensor-based control mechanisms, serving as the eyes and ears of the motor system.

Once these sensors detect the motor's position, they transmit this critical information to the processing module. Subsequently, the processing module, equipped with sophisticated algorithms, interprets this data and orchestrates the energization of motor phases accordingly. This seamless coordination between sensing technologies and processing modules ensures precise and efficient control over the motor's operation, enabling a wide array of industrial applications to thrive with optimal performance and reliability.

In contrast to sensor-based control mechanisms, sensor-less control methods represent a paradigm shift in motor operation regulation. Prominent among these methods are Field-Oriented Control (FOC) and back electromotive force (EMF) measurements, which employ innovative strategies to achieve precise control without relying on traditional sensors. In sensor-less control systems, the motor's position is not directly measured by external sensors. Instead, it is inferred through sophisticated algorithms and model-based techniques. Advanced artificial intelligence (AI) and machine learning (ML) algorithms play a crucial role in this process, leveraging complex mathematical models to estimate the motor's position with remarkable accuracy.

One key technique used in sensor-less control is Field-Oriented Control (FOC), which involves transforming the motor's phase currents and voltages from the stationary reference frame to a rotating reference frame. This allows for precise control of the motor's torque and flux, enhancing overall performance. Another approach involves utilizing back electromotive force (EMF) measurements. This method relies on detecting the voltage induced in the motor's windings due to its rotation, providing valuable information about the rotor position. By analyzing this back EMF signal, the control system can determine the motor's position and adjust the phase currents accordingly. Once the motor's position is estimated, the processing module of the controller generates signals for the motor phases based on these calculated positions.

These signals ensure that the motor operates smoothly and efficiently, even in the absence of direct sensor feedback. In summary, sensor-less control methods represent a sophisticated alternative to traditional sensor-based approaches, offering precise control and high performance through the integration of advanced algorithms and cutting-edge electronics.

An article “Artificial Neural Network Based Improved Modulation Strategy for Gallium Nitride (GaN)-based Inverter in EV” by Soumava Bhattacharjee elucidates a novel control technology, showcasing NN-based improved Space Vector Pulse Width Modulation (SVPWM) control for a GaN inverter in an electric vehicle (EV). A crucial challenge in GaN inverters involves attaining a high processing speed for complex algorithms during elevated switching frequencies at a reduced sample rate. This challenge is effectively addressed through the implementation of the proposed NN-based improved SVPWM, incorporating a low-cost Digital Signal Processing (DSP).

Another obstacle in GaN inverters pertains to switching loss, a pivotal factor influencing the inverter's performance. The results illustrate a notable reduction in switching loss with the introduced control, consequently enhancing the efficiency of the GaN inverter. Moreover, the findings indicate the superiority of the NN-based improved SVPWM over the conventional method in terms of time complexity and switching loss. Consequently, these results underscore the feasibility and stability of the proposed control.

A U.S. Pat. No. 9,812,981 assigned to DPM Technologies Inc discloses a system involving one or more Variable Configuration Controllers (VCC), capable of generating a diverse array of combinations involving series or parallel couplings of coils, windings, or inductive elements within an electromotive machine, such as a generator or electric motor.

These VCC systems are equipped with a number of bridge rectifiers, along with a first set of switches designed to selectively couple pairs of coils in series or parallel on the AC side of the bridge rectifiers. The unique design of the bridge rectifiers in these systems contributes to automatic electrical isolation of coils in the event of open circuit occurrences, low voltage situations, or short circuit conditions. This feature enhances the overall safety and reliability of the electric machine.

Furthermore, the system incorporates a second set of switches, each possessing distinct performance characteristics such as speed and loss, differing from those in the first set of switches. These second set switches are strategically coupled in parallel with corresponding switches from the first set, adding a layer of flexibility and adaptability to the configuration, allowing for optimization based on specific operational requirements. Additionally, power factor correction mechanisms are integrated into the system, further refining its performance and ensuring efficient energy utilization.

Another Chinese Patent CN105207557 assigned to Zhengzhou Zhi Drive Technology Co., Ltd. discloses a highly intelligent motor control method. In this method, the three-phase current of a permanent magnet synchronous motor (PMSM) is acquired through a current detector. Additionally, four position signal detectors are employed to individually detect the positions of magneto-1, magneto-2, magneto-3, and magneto-4. The rotor-position signal is then calculated based on the information gathered from these detectors, resulting in four synchronized rotor position signals for the motor. The control method proceeds by assessing the equality of the rotor-position signals from the magneto-1, the magneto-2, the magneto-3, and the magneto-4.

This determination is crucial for activating the current controller on the d-q axis to maintain a constant current. Subsequently, the inverter is employed to control the magneto-1, the magneto-2, the magneto-3, and the magneto-4 concurrently, aligning them with the desired setting signal for optimal operation.

This innovative approach offers several advantages, including high efficiency, robust driving capability, cost-effectiveness, and simplicity in control. The disclosed method is practical and reliable, demonstrating superior drivability. Overall, the invention represents a significant advancement in intelligent motor control, combining efficiency, cost-effectiveness, simplicity, and reliability to enhance the driving experience. However, the method does not incorporate any AI-based algorithms for controlling motor operations.

Another PCT published application, WO1024022851, assigned to Siemens Aktiengesellschaft, discloses a method of training a machine learning model for detecting one or more faults associated with at least one component of a drivetrain. The drivetrain includes a motor connected to a motor controller within an industrial facility. The motor controller is capable of monitoring and controlling the motor. Accordingly, the motor controller is connected to a number of sensors mounted on the motor. The number of sensors includes a magnetic field sensor to measure magnetic field strength along one or more axes of the motor.

The motor controller is configured to receive sensor data from the number of sensors and determine the condition of the motor based on this sensor data. The motor controller is connected to a training module for receiving the trained machine learning model. The training module is connected to a simulation model used for training the machine learning model, which, after training, is provided to the motor controller. Using the simulation model of the motor, the machine learning model is trained by the training module. This allows for the training of the machine learning model without requiring a significant volume of real motor data, thereby resulting in easy and fast deployment of the machine learning model.

A Korean patent, KR102133385, assigned to P&C Co., Ltd., provides an artificial intelligence device that offers a real-time diagnosis service for an induction motor and a method of operating the same. The device includes a real-time data storage unit that collects and stores vibration data, magnetic field data, and temperature data output from the A/D conversion unit in real time.

A three-way time-frequency data generator converts the vibration data and magnetic field data stored in the real-time data collection/storage unit into vibration data and magnetic field data in the frequency domain. It diagnoses and estimates the operating state of the induction motor by using the frequency domain data generated by the three-way time-frequency data generator, along with the time-domain temperature data stored in the real-time data collection/storage unit.

A defect diagnosis and prediction learning data generation unit generates defect diagnosis data and predictive learning data through machine learning, based on the diagnosis and estimation of the operation state diagnosis estimation unit. Although the patent disclosed herein provides a real-time diagnosis service for an induction motor using an artificial intelligence device, it does not provide any information regarding the optimization of the operation of the motor or generator coils.

A US publication, 20170031331, assigned to Fanuc Corp., discloses a machine learning apparatus that learns a condition associated with the gain of a magnetic flux controller and the time constant of a magnetic flux estimator in a motor control apparatus. The machine learning apparatus includes a state observation unit that observes a state variable defined by at least one of the following: data relating to the acceleration of a motor, data relating to the jerk of the motor, and data relating to the acceleration time of the motor. It also includes a learning unit that learns the condition associated with the gain of the magnetic flux controller and the time constant of the magnetic flux estimator according to a training data set defined by the state variable.

Although the patent disclosed herein provides a real-time diagnosis service for an induction motor using an artificial intelligence device, it does not offer any information regarding the optimization of motor or generator coil operation. This represents an intriguing gap in the literature, as there have been no studies exploring the use of sensors to measure the magnitude of magnetic flux density within the air gap and subsequently adjusting electromotive machine phases to achieve optimal flux conditions and maximum energy efficiency. This novel approach shifts the focus from merely optimizing electromotive machine operation to prioritizing energy conservation. Unlike conventional algorithms that aim for optimal electromotive machine operation, the proposed methodology prioritizes maximizing energy savings while ensuring the electromotive machine operates under optimal conditions.

Indeed, a notable void persists in the existing literature, presenting an intriguing opportunity for innovation. Surprisingly, no prior studies have ventured into the realm of utilizing sensors to gauge the magnitude and phase angle of magnetic flux density within the air gap, a critical aspect of motor performance. This unexplored territory opens the door to a novel approach wherein sensors can be leveraged to measure flux density, allowing for precise adjustments to the electromotive machine phases. By calibrating these adjustments to achieve optimal flux conditions, this methodology holds the promise of maximizing energy savings in electromotive machine operation.

This shift in focus represents a departure from conventional paradigms, which primarily aim at optimizing electromotive machine operation without explicitly considering energy conservation. By prioritizing energy savings alongside operational efficiency, our proposed methodology introduces a paradigm shift in electromotive machine control strategies. Rather than solely striving for optimal electromotive machine performance, the approach places equal emphasis on minimizing energy consumption, thereby aligning with contemporary sustainability goals and environmental imperatives.

Through this innovative approach, the present invention aims to redefine the boundaries of electromotive machine control methodologies and pave the way for more sustainable and energy-efficient electromotive machine systems. By integrating magnetic flux sensor technology with advanced control algorithms, the present invention seeks to unlock new possibilities for enhancing electromotive machine performance while simultaneously reducing energy consumption, thus contributing to a greener and more sustainable future.

It is apparent that numerous methods and systems have been developed in the prior art that are adequate for various purposes. However, while these inventions may be suitable for specific purposes they address, they would not be suitable for the purposes of the present invention as previously described. Therefore, there is a need to provide an intelligent electromotive machine control system. This system utilizes magnetic flux density sensors strategically positioned within the electromotive machine assembly to continuously monitor and measure flux levels. It optimizes the operation of electromotive machine coils based on the feedback received from these magnetic flux sensors.

### SUMMARY OF THE INVENTION

The present invention substantially avoids the disadvantages and limitations of prior art by introducing an intelligent electromotive machine control system. This system optimizes the performance of electromotive machines such as motors or generators by leveraging real-time feedback from magnetic flux sensors, representing a sophisticated approach. It involves strategically positioning magnetic flux sensors within the electromotive machine assembly to continuously monitor and measure magnetic flux levels and directions.

In preferred embodiment of the present invention, the present invention provides an electromotive machine control system for controlling the electromotive machine. The electromotive machine assembly including a stator element that includes a number of electromagnetic or permanent magnetic members arranged in a pre-defined configuration. In one embodiment of the present invention, the stator element includes both electromagnetic and permanent magnetic members. In alternative embodiment of the present invention, the stator element includes either only electromagnetic members or only permanent magnetic members.

Further, the electromotive machine assembly includes a motion element that includes at least second set of a number of electromagnetic or permanent magnetic members arranged in a predefined configuration. Further, the electromotive machine assembly includes an air-gap between the stator and the motion element to allow the magnetic flux to pass through.

the electromotive machine control system includes a number of magnetic flux sensors that are positioned in the air-gap or around the magnetic members to continuously monitor the magnetic flux behavior to determine the magnitude and phase angle of the magnetic flux density or one or more other parameters associated with the magnetic flux in real-time to compute a sensed data. Further, the electromotive machine control system includes a sensing unit that analyzes magnitude and phase angle of the magnetic flux density or other parameters, transmitting the signals to a processor for decision-making.

Further, the electromotive machine control system includes a processing unit that includes a memory to store executable instructions for controlling the electromotive machine. Further, the processing unit includes a processor executing the stored instructions, receiving digital signals to generate processed signals aimed at achieving minimal energy consumption while maintaining required electromotive machine operation. Furthermore, the electromotive machine control system includes an electromotive machine control unit that receives the processed signal from the processor. Based on these processed signals, it activates or deactivates one or more switches associated with electromagnetic members to control the electromotive machine.

The primary objective of this intelligent electromotive machine control system is to dynamically adjust and optimize the operation of electromagnetic members, such as motor or generator coils, based on feedback received from the magnetic flux sensors. By continuously analyzing the magnetic flux data, the electromotive machine control system adaptively regulates the current supplied to the electromagnetic members. This real-time adjustment aims to achieve maximum energy savings and appropriate use of input energy by optimally controlling the magnetic field within the electromotive machine according to the operational requirements at any given moment.

The feedback loop from the magnetic flux sensors enables the electromotive machine control system to make instantaneous decisions regarding the magnitude and timing of the current supplied to the electromagnetic members. This responsive approach ensures that the electromotive machine operates at peak efficiency with minimal input energy across a range of operating conditions, minimizing energy use and losses while enhancing overall performance.

Additionally, this intelligent electromotive machine control system incorporates advanced algorithms and artificial intelligence to predict and pre-emptively adjust the electromotive machine parameters based on anticipated changes in load or speed requirements. Such predictive capabilities contribute to further optimizing energy usage and enhancing the responsiveness of the electromotive machine.

Overall, the integration of magnetic flux sensor feedback into the electromotive machine control system enhances the intelligence and adaptability of the electromotive machine operation, ultimately resulting in a more energy-efficient and high-performance electromotive machine system. This approach aligns with contemporary efforts to develop smart and sustainable technologies for a wide range of applications, from industrial machinery to electric vehicles.

In addition to utilizing magnetic flux sensor feedback, the electromotive machine control system incorporates a sophisticated coil configuration strategy to further enhance the energy savings. The electromagnetic members, such as motor or generator coils, are interconnected in a manner that allows for precise control over individual coils or combinations of coils, following a carefully designed patterns.

This strategic arrangement enables the optimization of electromotive machine performance by tailoring the electrical current flow to meet specific operational demands. The configuration of the electromagnetic members is designed to provide flexibility in the control strategy. The control system is capable to activate and manipulate individual electromagnetic members, tailoring the magnetic field generated by each electromagnetic member to the required specifications. This level of granularity in control allows for fine-tuning the electromotive machine response to varying loads and operating conditions, contributing to increased energy savings.

Moreover, the electromotive machine control system dynamically combines specific electromagnetic members in response to the electromotive machine operational requirements. By implementing various electromagnetic member combinations, the system adapts to different torque demands and speed variations. This adaptive control mechanism ensures that the electromotive machine operates optimally across a wide range of scenarios, promoting energy savings without compromising performance.

The control patterns for activating individual electromagnetic members or combinations are carefully crafted based on extensive analysis and optimization algorithms. These patterns consider factors such as load distribution, speed requirements, and energy consumption goals. The system can continuously analyze the real-time feedback from the magnetic flux sensors to adjust the electromagnetic member activation patterns dynamically, ensuring that the electromotive machine adapts swiftly to changes in the operating environment.

In summary, the integration of a configurable electromagnetic member arrangement in the electromotive machine control system provides an additional layer of adaptability and precision. By controlling individual electromagnetic members or combinations of electromagnetic members according to a carefully devised patterns, the electromotive machine achieves maximum efficiency across a diverse set of operating conditions, making it a versatile and energy-efficient solution for various applications.

The electromotive machine control system providing a robust foundation for electromotive machine control, the electromotive machine control system introduces a range of intelligent features. These include advanced diagnostics, remote monitoring capabilities, and adaptive control strategies that respond dynamically to changing operational conditions.

In addition to this, the electromotive machine control system incorporates smart technologies, positioning the IMCS as a crucial asset for industries aiming to enhance operational efficiency, minimize downtime, and stay ahead of the curve in the rapidly evolving landscape of industrial automation. By harnessing data analytics, the IMCS empowers industrial facilities to make informed decisions, driving productivity and ensuring a competitive edge in today's technologically driven environment.

Other objectives and aspects of the invention will become apparent from the following detailed description, taken in conjunction with the accompanying drawings, which illustrate, by way for example, the features in accordance with embodiments of the invention.

To the accomplishment of the above and related objects, this invention may be embodied in the form illustrated in the accompanying drawings, attention being called to the fact, however, that the drawings are illustrative only, and that changes may be made in the specific construction illustrated and described within the scope of the appended claims.

Although, the invention is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations, to one or more of the other embodiments of the invention, whether or not such embodiments are described and whether or not such features are presented as being a part of a described embodiment. Thus, the breadth and scope of the present invention should not be limited by any of the above-described exemplary embodiments.

The presence of broadening words and phrases such as “one or more,” “at least,” “but not limited to” or other like phrases in some instances shall not be read to mean that the narrower case is intended or required in instances where such broadening phrases may be absent.

### BRIEF DESCRIPTION OF THE DRAWINGS

The accompanying drawings illustrate various embodiments of systems, methods, and embodiments of various other aspects of the disclosure. Any person with ordinary skills in the art will appreciate that the illustrated element boundaries (e.g. boxes, groups of boxes, or other shapes) in the figures represent one example of the boundaries. It may be that in some examples one element may be designed as multiple elements or that multiple elements may be designed as one element. In some examples, an element shown as an internal component of one element may be implemented as an external component in another and vice versa. Furthermore, elements may not be drawn to scale. Non-limiting and non-exhaustive descriptions are described with reference to the following drawings. The components in the figures are not necessarily to scale, emphasis instead being positioned upon illustrating principles. Furthermore, the drawings may contain text or captions that may explain certain embodiments of the present invention. This text is included for illustrative, non-limiting, explanatory purposes of certain embodiments detailed in the present invention. In the drawings:

Embodiments of the invention are described with reference to the following figures. The same numbers are used throughout the figures to reference like features and components. The features depicted in the figures are not necessarily shown to scale. Certain features of the embodiments may be shown exaggerated in scale or in somewhat schematic form, and some details of elements may not be shown in the interest of clarity and conciseness.

FIG. 1 illustrates an electromotive machine (e.g., motor, generator) control system in accordance with the present invention;

FIG. 2 illustrates a motor control system in accordance with the present invention;

FIG. 3 illustrates positioning of a number of magnetic flux density sensors in an electromotive machine in accordance with the present invention;

FIG. 4 illustrates a method for controlling operations of the electromotive machine in accordance with the present invention;

FIG. 5 illustrates a graph focusing on a battery discharging curve for a brushless DC motor operating under no-load conditions;

FIG. 6 illustrates a graph focusing on a battery discharging curve for a brushless DC motor operating at 70W load conditions;

FIG. 7 illustrates a graph focusing on the input power versus time curves of a brushless DC motor used in a mobile robot; and

FIG. 8 illustrates a graph focusing on the input power versus speed level curve of a brushless DC ceiling fan motor having a power rating of 36 W.

### DETAILED DESCRIPTION OF THE INVENTION

The present specification is directed towards multiple embodiments. The following disclosure is provided in order to enable a person having ordinary skill in the art to practice the invention. Language used in this specification should not be interpreted as a general disavowal of any one specific embodiment or used to limit the claims beyond the meaning of the terms used therein. The general principles defined herein may be applied to other embodiments and applications without departing from the spirit and scope of the invention. Also, the terminology and phraseology used is for the purpose of describing exemplary embodiments and should not be considered limiting. Thus, the present invention is to be accorded the widest scope encompassing numerous alternatives, modifications and equivalents consistent with the principles and features disclosed. For purpose of clarity, details relating to technical material that is known in the technical fields related to the invention have not been described in detail so as not to unnecessarily obscure the present invention.

In the description and claims of the application, each of the words “units” represents the dimension in any units such as centimeters, meters, inches, foots, millimeters, micrometer and the like and forms thereof, are not necessarily limited to members in a list with which the words may be associated.

In the description and claims of the application, each of the words “comprise”, “include”, “have”, “contain”, and forms thereof, are not necessarily limited to members in a list with which the words may be associated. Thus, they are intended to be equivalent in meaning and be open-ended in that an item or items following any one of these words is not meant to be an exhaustive listing of such item or items, or meant to be limited to only the listed item or items. It should be noted herein that any feature or component described in association with a specific embodiment may be used and implemented with any other embodiment unless clearly indicated otherwise.

Regarding applicability of 35 U.S.C. § 112, ¶6, no claim element is intended to be read in accordance with this statutory provision unless the explicit phrase “means for” or “step for” is actually used in such claim element, whereupon this statutory provision is intended to apply in the interpretation of such claim element.

Furthermore, it is important to note that, as used herein, “a” and “an” each generally denotes “at least one,” but does not exclude a number unless the contextual use dictates otherwise. When used herein to join a list of items, “or” denotes “at least one of the items,” but does not exclude a number of items from the list. Finally, when used herein to join a list of items, “and” denotes “all of the items of the list.”

The following detailed description refers to the accompanying drawings. Wherever possible, the same reference numbers are used in the drawings and the following description to refer to the same or similar elements. While many embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims. The present invention contains headers. It should be understood that these headers are used as references and are not to be construed as limiting upon the subjected matter disclosed under the header.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

The presence of broadening words and phrases such as “one or more,” “at least,” “but not limited to” or other like phrases in some instances shall not be read to mean that the narrower case is intended or required in instances where such broadening phrases may be absent.

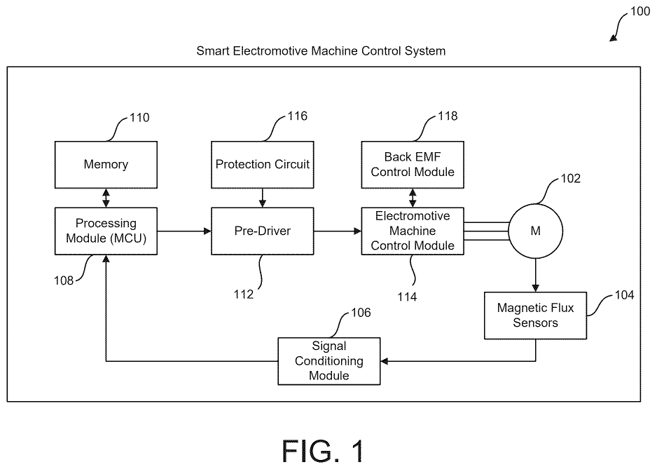

FIG. 1 illustrates a smart electromotive machine control system (100) for controlling operations of an electromotive machine. The smart electromotive machine control system (100) includes an electromotive machine assembly (102) that includes a number of electromagnetic or permanent magnetic members arranged in a pre-defined configuration. The electromotive machine assembly including a stator element that includes a number of electromagnetic or permanent magnetic members arranged in a pre-defined configuration.

In one embodiment of the present invention, the stator element includes both electromagnetic and permanent magnetic members. In alternative embodiment of the present invention, the stator element includes either only electromagnetic members or only permanent magnetic members. The electromotive machine assembly must have at least one electromagnetic member. The number of electromagnetic members is interconnected in a manner that allows precise control over individual electromagnetic members or combination of electromagnetic members and further enabling optimization of the performance of the electromotive machine by tailoring the electrical current flow to meet specific operational demands. The number of electromagnetic members arranged in a strategic configuration. In one embodiment of the present invention, the number of electromagnetic members is arranged in series or parallel configuration depending on the requirement.

Further, electromotive machine assembly (102) includes a number of magnetic flux sensors (104) positioned within the air-gap or around the number of electromagnetic or permanent magnetic members. These sensors are configured to continuously monitor the magnetic flux and compute, in real time for each phase, the magnitude and phase angle of the magnetic flux density, along with one or more other parameters associated with the magnetic flux. The other parameters associated with the magnetic flux include either the polarity of the magnetic flux, the direction of the magnetic flux, the switching frequency, the duty cycle, or a combination thereof.

Further, the magnetic flux density sensor-based smart electromotive machine control system (100) includes a signal conditioning module (106) that includes a sensor interface for analyzing one or more parameters associated with the magnetic flux. Further, the signal conditioning module (106) can include a comparator for comparing one or more parameters of the magnetic flux with a set of user-defined or previously calculated parameters associated with the magnetic flux. Further, signal conditioning module (106) includes a signal processing unit for generating a signal based on comparison of the one or more parameters with the pre-defined parameters.

Further, the smart electromotive machine control system (100) includes an intelligent processing module (108) that includes a memory (110) to store executable instructions for controlling the electromotive machine. Further, the processing module (108) can include an AI-based processor to execute the executable instructions stored within the memory. The AI-based processor receives the signal to generate a processed signal. The processing module (108) includes an AI or ML algorithm that analyses the magnetic flux behavior and provides the signal to control operations of the electromotive machine.

The processing module (108) receives user-specified parameters related to the magnetic flux and electromotive machine operation requirements and stores them in the memory module (110). The user-specified parameters associated with electromotive machine operation may include the speed of the motion element, direction of the motion element, torque applied, acceleration time, temperature, machine current, machine voltage, active power, reactive power, input electrical characteristics, frequency, magnetic flux parameters, dynamic parameters, application-specific parameters, or a combination thereof. The processor makes instantaneous decisions to energize the number of electromagnetic members to evaluate the speed of the motion element and determine the desired speed and switching pattern of the electromagnetic members. The processor energizes the number of electromagnetic members to gradually adjust the switching frequency and duty cycle if the desired speed is not achieved.

The processing module (108) includes a module for generating a series of pulses that control the driving of the electromotive machine with a series of ‘ON-OFF’ pulses. It further varies the duty cycle and the fraction of time in which the output voltage is ‘ON’ compared to when it is ‘OFF’ in the series of pulses. The pattern of ON-OFF pulses is carefully determined to achieve maximum energy savings while maintaining the magnetic flux at optimal levels. This involves a precise control strategy where the electromagnet is alternately energized and de-energized according to a specific sequence.

To maximize energy savings, the ON-OFF pulse pattern is designed to minimize the time the electromagnet is actively drawing power, thereby reducing overall energy consumption. During the ‘ON’ phase, the electromagnet is energized, creating a magnetic field necessary for operation. The duration and frequency of this ‘ON’ phase are calibrated to ensure that the magnetic flux reaches and sustains its optimal level.

Conversely, during the ‘OFF’ phase, the electromagnet is de-energized, which conserves energy by stopping the current flow. The duration of the ‘OFF’ phase is managed to prevent any significant drop in the magnetic flux that could affect performance. The goal is to balance the periods of energy consumption with those of conservation, ensuring that the magnetic field remains stable and effective while minimizing energy usage.

The optimization of the ON-OFF pulse pattern is achieved through sophisticated algorithms that take into account factors such as load conditions, operational demands, and core material properties. By doing so, the system can maintain the desired magnetic flux while achieving significant energy savings, leading to improved efficiency and reduced operational costs.

Further, the smart electromotive machine control system (100) includes an electromotive machine control module (114) for receiving the processed signal from the intelligent processor (108). The electromotive machine control module (114) regulates flow of current in the number of electromagnetic members based on the processed signal by activating or deactivating one or more switches for controlling the electromotive machine. The electromotive machine control module configured to choose activation and manipulation of single electromagnetic members of the number of electromagnetic members or combination of electromagnetic members of the number of electromagnetic members for regulating the flow of current thereby allowing fine tuning of the electromotive machine operation to varying loads and operating conditions.

The number of electrical switches includes, but is not limited to, Bipolar Junction Transistors (BJT), Field-Effect Transistors (FET), Junction Field-Effect Transistors (JFET), Metal-Oxide-Semiconductor Field-Effect Transistors (MOSFET), Gallium Nitride (GaN) transistors, and Insulated-Gate Bipolar Transistors (IGBT). The electromotive machine control module dynamically adjusts and optimizes the operation of the number of electromagnetic members based on feedback received in real-time from the magnetic flux density sensors. The number of electromagnetic members is interconnected in a manner that allows precise control over individual electromagnetic members or combinations thereof, further enabling the optimization of the performance of electromotive machine by tailoring the electrical current flow to meet specific operational demands while keeping the magnetic flux at an optimum level.

The number of magnetic flux sensors determines flux levels by measuring the magnetic flux passing through the sensor. The control unit chooses the activation and manipulation of single electromagnetic members or combinations thereof, tailoring the magnetic field generated by each electromagnetic member, allowing fine-tuning of the electromotive machine to varying loads and operating conditions, thereby operating in the most energy-efficient mode.

The feedback loop from the number of magnetic flux sensors enables the processing module to make instantaneous decisions regarding the magnitude and timing of the current supplied to the number of electromagnetic members of the electromotive machine. The electromotive machine control module drives the electromotive machine in the same or different directions, at the same or different speeds or at the same or different torques based on signals from the processor. The speed or torque of the electromotive machine may be varied by adjusting the switching frequency and amplitude of the current through the electromagnetic members.

In the present invention, the objective is to maintain optimal magnetic flux levels in the airgap during the entire operation of the electromotive machine. The selection of core material for the electromagnets is critical, particularly with regard to the residual magnetism of the core materials. In this context, residual magnetism can be advantageous because it contributes to maintaining a stable magnetic field even when the electromagnet is not actively energized. Core materials with appropriate levels of residual magnetism can help ensure that the magnetic flux remains at the desired level within the airgap, improving the performance and efficiency of the electromotive machine. By selecting core materials that retain a suitable amount of residual magnetism, the system can achieve more consistent magnetic flux, which is beneficial for applications where continuous magnetic presence or stability is required.

The pre-driver unit (112) and protection circuit (116) ensure precise control and protect the switching devices of the electromotive machine control module (114). The pre-drive circuit (112) prepares control signals for the power switching devices, ensuring they are at the correct voltage and current levels to effectively drive the electromotive machine (102). It also includes mechanisms like dead-time control to prevent short circuits. The electromotive machine protection circuit (116) includes features such as overcurrent protection, thermal protection, and undervoltage protection to safeguard the electromotive machine from various faults and adverse operating conditions.

The Back EMF Control Module (118) comprises capacitors designed to store energy from back electromotive force (EMF) when the supply to the electromagnetic members is switched off. The stored energy in the capacitors can subsequently be used to recharge the batteries or provide energy to an electromagnetic member or a number of electromagnetic members in subsequent cycles.

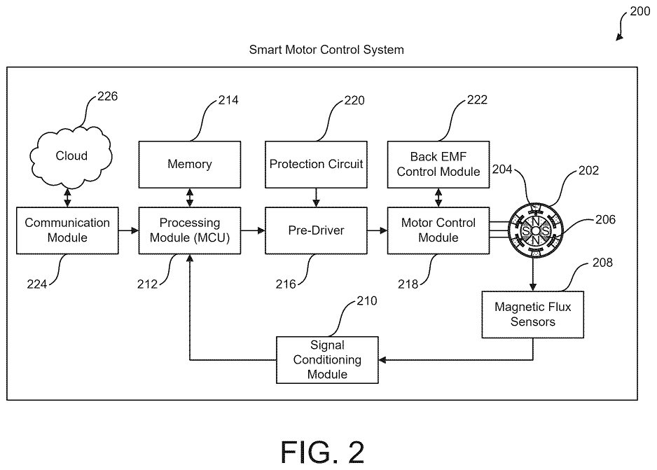

FIG. 2 illustrates a circuitry diagram of the motor control system (200) in accordance with the present invention. The motor control system (200) controls the operations of a motor. The motor control system (200) includes a motor assembly (202) that consists of a number of electromagnets (coils) (204) and permanent magnets (206) arranged in a predefined configuration. The number of coils (204) are interconnected in a manner that allows precise control over individual coils or combinations thereof, further enabling optimization of the performance of the motor by tailoring the electrical current flow to meet specific operational demands. The number of coils (204) are arranged in a strategic configuration. In one embodiment of the present invention, the number of coils (204) is arranged in series or parallel configurations depending on the requirement.

Further, the motor control assembly (202) includes a number of magnetic flux sensors (208) positioned in the air gap or around the number of coils (204). These sensors are configured to continuously monitor the magnetic flux behavior and determine, in real time for each phase, the magnitude and phase angle of the magnetic flux density or one or more other parameters associated with the magnetic flux. The number of other parameters associated with the magnetic flux is either the polarity of the magnetic flux, the direction of the magnetic flux, the switching frequency, the duty cycle, or a combination thereof.

Further, the smart motor control system (200) includes a signal conditioning module (210) that includes a sensor interface for analyzing the one or more parameters associated with the magnetic flux. Further, the signal conditioning module (210) can include a comparator for comparing one or more parameters of the magnetic flux with the number of user pre-defined parameters associated with the magnetic flux. Further, signal conditioning module (210) includes a signal processing unit for generating a signal, based on comparison of the one or more parameters with the pre-defined parameters.

Further, the smart motor control system (200) includes an intelligent processing module (212) that includes a memory module (214) to store executable instructions for controlling the motor. Further, the processing module (212) can include an AI-based processor to execute the executable instructions stored within the memory. The AI-based processor receives the signal to generate a processed signal. The processing module (212) includes an AI or ML algorithm that analyses the magnetic flux behavior and provides signals to control the operations of the motor.

The processing module (212) receives user-specified parameters related to the magnetic flux and motor operation requirements and stores them in the memory module (214). The user-specified parameters associated with motor operation may include the speed of the rotor, rotating direction of the rotor, torque applied, acceleration time, temperature, machine current, machine voltage, active power, reactive power, input electrical characteristics, frequency, magnetic flux parameters, dynamic parameters, application-specific parameters, or a combination thereof.

The processor makes instantaneous decisions to energize the number of coils (204) to analyze the speed of the rotor for achieving the desired speed and energizing pattern of the number of coils (204). The processor energizes the number of coils (204) to gradually adjust the switching frequency and duty cycle to achieve the desired speed.

The processing module (212) includes a module for generating a series of pulses that control driving of the motor with a series of “ON-OFF” pulses and further varies the duty cycle. The pattern of ON-OFF pulses is carefully determined to achieve maximum energy savings while maintaining the magnetic flux at optimal levels. This involves a precise control strategy where the electromagnet is alternately energized and de-energized according to a specific sequence. To maximize energy savings, the ON-OFF pulse pattern is designed to minimize the time the electromagnet is actively drawing power, thereby reducing overall energy consumption.

During the ‘ON’ phase, the electromagnet is energized, creating a magnetic field necessary for operation. The duration and frequency of this ‘ON’ phase are calibrated to ensure that the magnetic flux reaches and sustains its optimal level. Conversely, during the ‘OFF’ phase, the electromagnet is de-energized, which conserves energy by stopping the current flow. The duration of the ‘OFF’ phase is managed to prevent any significant drop in the magnetic flux that could affect performance.

The goal is to balance the periods of energy consumption with those of conservation, ensuring that the magnetic field remains stable and effective while minimizing power usage. The optimization of the ON-OFF pulse pattern is achieved through sophisticated algorithms that take into account factors such as load conditions, operational demands, and core material properties. By doing so, the system can maintain the desired magnetic flux while achieving significant energy savings, leading to improved efficiency and reduced operational costs.

Further, the smart motor control system (200) includes a motor control module (218) for receiving the processed signal from the processing module (212). The motor control module (218) regulates flow of current in the number of coils (204) based on the processed signal by activating or deactivating one or more switches for controlling the motor.

The motor control module (218) configured to choose activation and manipulation of single coils of the number of coils or combination of coils of the number of coils for regulating the flow of current thereby allowing fine tuning of the motor to varying loads and operating conditions. The pre-driver unit (216) and protection circuit (220) ensure precise control and protect the switching devices of the motor control module (218). The pre-drive circuit (216) prepares control signals for the power switching devices, ensuring they are at the correct voltage and current levels to effectively drive the motor (202). It also includes mechanisms like dead-time control to prevent short circuits. The motor protection circuit (220) includes features such as overcurrent protection, thermal protection, and undervoltage protection to safeguard the motor (202) and motor control module (218) from various faults and adverse operating conditions.

The Back EMF Control Module (222) comprises capacitors designed to store energy from back electromotive force (EMF) when the supply to the coils is switched off. The stored energy in the capacitors can subsequently be used to recharge the batteries or provide energy to a coil or a number of coils in subsequent cycles.

The communication module (224) connected to the processing module (212) facilitates communication with various peripherals and a cloud network. This setup enables the microcontroller to send and receive data, allowing for real-time monitoring and control. Communication standards such as I2C (Inter-Integrated Circuit) and others, like SPI (Serial Peripheral Interface) and UART (Universal Asynchronous Receiver-Transmitter), are commonly used to interface with peripherals.

These standards provide efficient data exchange mechanisms between the microcontroller and connected devices, such as sensors, actuators, and memory modules. Additionally, the communication module includes protocols like Wi-Fi, Bluetooth, or Ethernet, enabling the microcontroller to connect to the cloud (226). This connection allows for remote data access, processing, and control, enhancing the capabilities of the system by leveraging cloud-based resources and services.

The system is configured to store magnetic flux data of the motor, including but not limited to the magnitude and phase angle of the magnetic flux density, the polarity and direction of the magnetic flux, the switching frequency, and the duty cycle, in a cloud-based storage system at predetermined intervals such as every microsecond, millisecond, second, minute, or other selectable time periods. The magnetic flux data is highly sensitive and provides comprehensive information regarding the operation of the motor, user behavior, and motor operating environment. Such data can subsequently be utilized for advanced data analytics, AI modeling, and predictive diagnostics to enhance motor performance, reliability, and efficiency.

Cloud-based data will be used to provide end users with AI-assisted predictions of motor behavior, energy usage, fault detection, and application environment detection. By leveraging cloud computing, vast amounts of data collected from the motor and its operating environment will be processed and analyzed in real-time. AI algorithms will be used to analyze historical and real-time data to predict motor performance, identifying patterns and anomalies that may indicate potential issues.

For motor behavior, AI can predict parameters like wear and tear, efficiency changes, and optimal operating conditions. Regarding energy usage, AI can provide insights into consumption patterns as well as battery charging patterns, helping users optimize energy efficiency and reduce costs. Fault detection is enhanced by ability of AI to detect subtle signs of impending failures, enabling preventive maintenance and reducing downtime. Finally, application environment detection allows the system to adapt to varying conditions, ensuring optimal performance across different scenarios. By integrating these AI-assisted predictions, end users gain valuable insights, allowing for proactive management and improved operational efficiency of their motor systems.

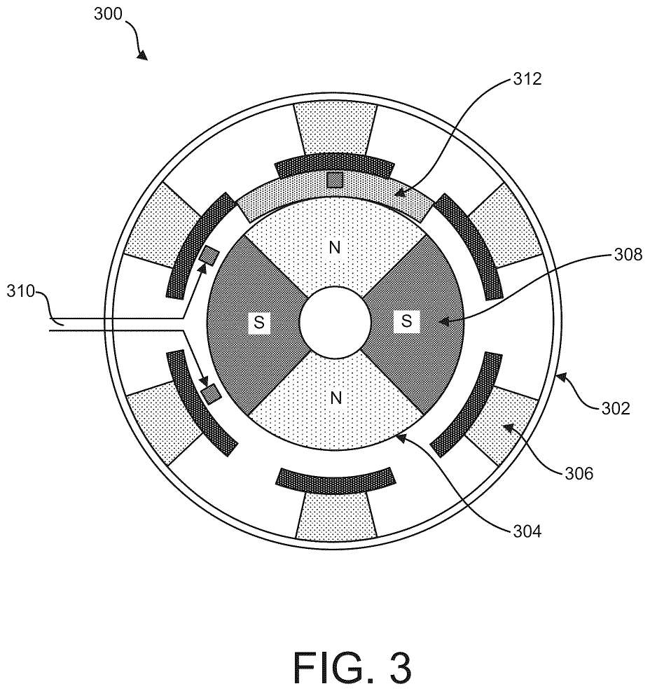

FIG. 3 illustrates positioning of a number of magnetic flux sensors (208) in a motor control system (200) in accordance with the present invention. The motor (300) includes a stator (302) and a rotor (304). A series of electromagnets or coils (306) are positioned on the stator (302). A series of permanent magnets (308) are positioned on the rotor (304). In another embodiment, the rotor can also have electromagnets or coils. The number of magnetic flux sensors (310) are positioned strategically within an air gap (312) between the rotor (304) and the stator (302) of the motor (300).

The number of magnetic flux sensors (310) are arranged in arrays, which are positioned within the air-gap (312) between the rotor (304) and the stator (302) of the motor (300). These arrays can be mounted on a PCB but are not limited to this configuration. The arrays may be vertical, horizontal, or a combination of both. In one alternative embodiment of the present invention, the number of magnetic flux sensors (310) arranged at an angle with respect to the air gap between the rotor (304) and the stator (302) of the motor (300).

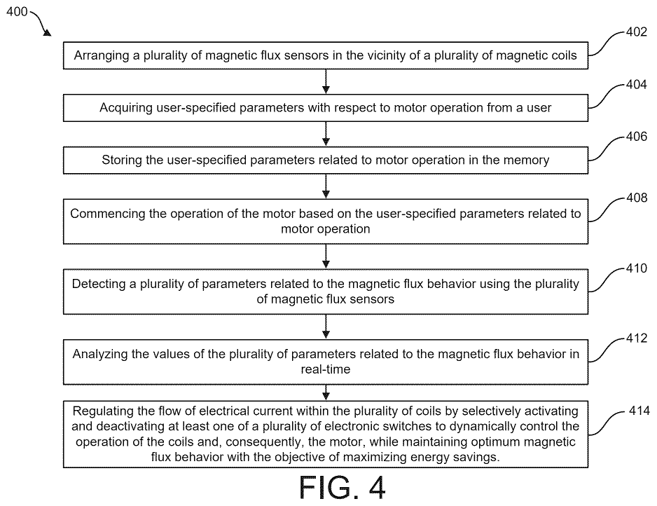

FIG. 4 illustrates a method (400) for controlling the operations of the motor (300) in accordance with the present invention. The method (400) comprises a step (402) of arranging a number of magnetic flux sensors in the vicinity of a number of electromagnetic coils. Further, the method (400) includes a step (404) of acquiring one or more user-specified parameters based on the magnetic flux, speed of the rotor, rotation direction of the rotor, torque, and specific load from a user. Further, the method (400) includes a step (406) of storing the user-specified parameters in the memory module (214). Further, the method (400) includes a step (408) of commencing operation of the motor based on the user-specified parameters.

Further, the method (400) includes a step (410) of detecting a number of parameters with respect to the magnetic flux by the number of magnetic flux sensors (310). Further, the method (400) includes a step (412) of analyzing value of the number of parameters with respect to the magnetic flux in real-time. Further, the method (400) includes a step (414) of regulating the flow of electrical current within the number of coils by selectively activating and deactivating atleast one of a number of electronic switches to dynamically control the operation of the coils and, consequently, the motor.

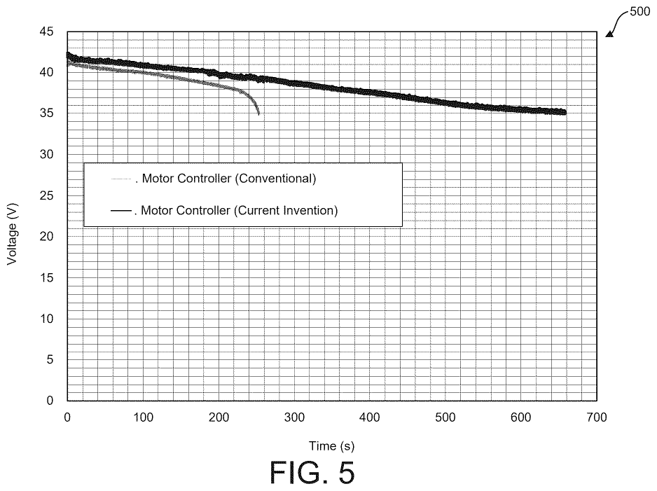

FIG. 5 illustrates a graph (500) focusing on a battery discharging curve for a brushless DC motor operating under no-load conditions. Example 1: FIG. 5 shows the battery discharging curve for a brushless DC motor with a power rating of 350W, a rated voltage of 36V, and a rated speed of 3000 rpm, equipped with 27 stator electromagnets and 30 rotor permanent magnets, operating under no-load conditions. The comparison is between the performance of a conventional motor controller and a motor controller incorporating the current invention. As illustrated in FIG. 5, the motor controller with the current invention operates for more than three times longer compared to the conventional motor controller before the battery discharges below 35V. This demonstrates that the motor controller with the current invention consumes three times less energy compared to the conventional driver, highlighting its superior efficiency and extended operational time.

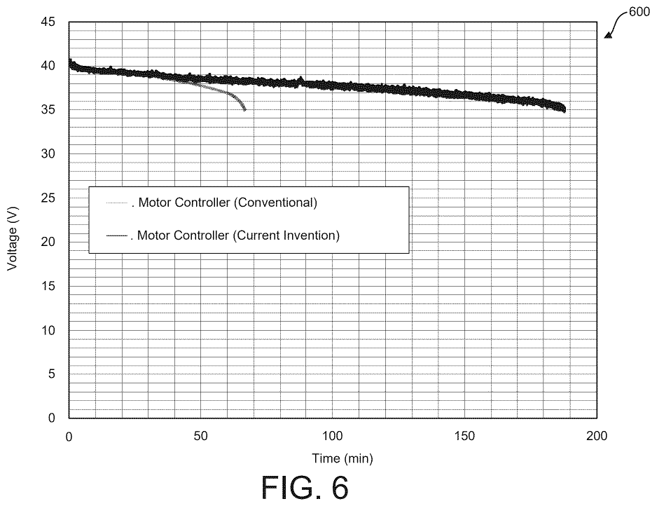

FIG. 6 illustrates a graph (600) focusing on a battery discharging curve for a brushless DC motor operating at 70W load conditions. Example 2: FIG. 6 shows the battery discharging curve for a brushless DC motor with a power rating of 350W, a rated voltage of 36V, and a rated speed of 3000 rpm, equipped with 27 stator electromagnets and 30 rotor permanent magnets, operating at 70W load conditions. The comparison is between the performance of a conventional motor controller and a motor controller incorporating the current invention. As illustrated in FIG. 6, the motor controller with the current invention operates for more than 2.7 times longer compared to the conventional motor controller before the battery discharges below 35V. This demonstrates that the motor controller with the current invention consumes significantly less energy compared to the conventional driver, highlighting its superior efficiency and extended operational time.

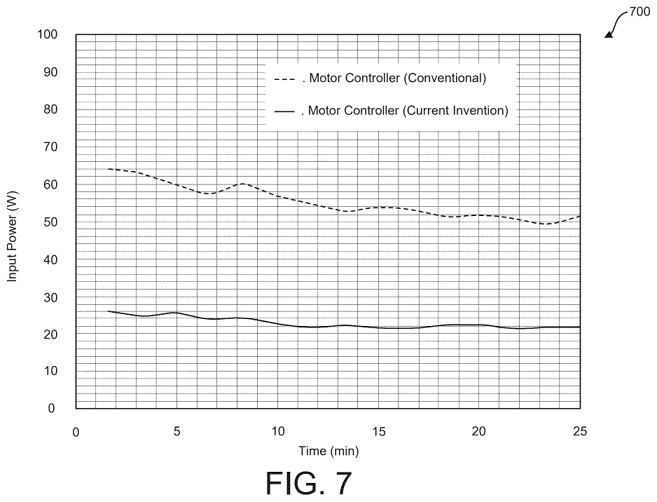

FIG. 7 illustrates a graph (700) focusing on the input power versus time curves of a brushless DC motor used in a mobile robot. Example 3: FIG. 7 illustrates the input power versus time curve of a brushless DC motor used in a mobile robot, having a power rating of 400 W, a rated voltage of 24 V, and a rated speed of 3000 rpm, and equipped with 15 stator electromagnets and 8 rotor permanent magnets, operating under real factory conditions. The comparison is made between the performance of a conventional motor controller and a motor controller incorporating the current invention. As shown in FIG. 7, the motor controller according to the present invention draws approximately 25 W of power, whereas the conventional motor controller draws between 50 W and 65 W. This demonstrates that the motor controller of the present invention consumes significantly less power and energy compared to the conventional driver, thereby offering superior energy savings and extended operational time.

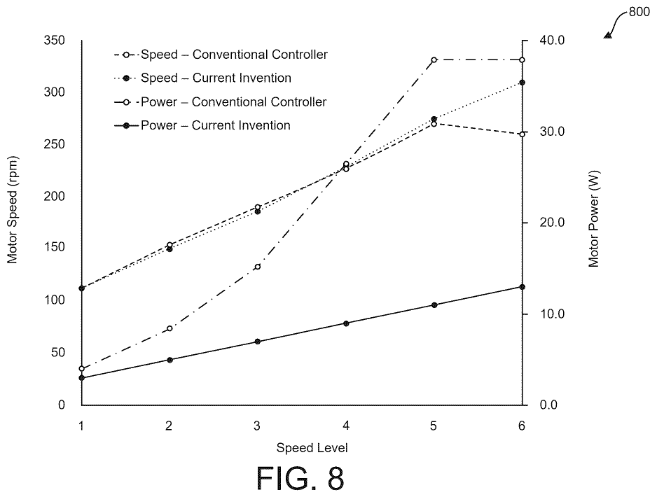

FIG. 8 illustrates a graph (800) focusing on the input power versus speed level curve of a brushless DC ceiling fan motor having a power rating of 36 W. Example 4: FIG. 8 illustrates the input power versus speed level curve of a brushless DC ceiling fan motor having a power rating of 36 W, a rated voltage of 24 V, and a rated speed of 300 rpm, and equipped with 12 stator electromagnets and 14 rotor permanent magnets, operating under varying speed conditions. The comparison is made between the performance of a conventional motor controller and a motor controller incorporating the present invention. As shown in FIG. 8, across all speed levels between 100 rpm and 300 rpm, the motor controller of the present invention draws 50% or more less power compared to the conventional controller. For example, at speed level 6 (corresponding to 300 rpm), the conventional controller draws approximately 37.5 W, whereas the controller of the present invention draws only about 13 W.

While illustrative implementations of the application have been described in detail herein, it is to be understood that the inventive concepts may be otherwise variously embodied and employed, and that the appended claims are intended to be construed to include such variations, except as limited by the prior art.

Reference throughout this specification to “one implementation” or “an implementation” means that a particular feature, structure, or characteristic described in connection with the implementation is included in at least one implementation of the present invention. Thus, the appearances of the phrases “in one implementation” or “in some implementations” in various places throughout this specification are not necessarily all referring to the same implementation. Furthermore, the particular features, structures, or characteristics may be combined in any suitable manner in one or more implementations.

Systems and methods describing the present invention have been described. It will be understood that the descriptions of some embodiments of the present invention do not limit the various alternative, modified, and equivalent embodiments which may be include within the spirit and scope of the present invention as defined by the appended claims. Furthermore, in the detailed description above, numerous specific details are set forth to provide an understanding of various embodiments of the present invention. However, some embodiments of the present invention may be practiced without these specific details. In other instances, well known methods, procedures, and components have not been described in detail so as not to unnecessarily obscure aspects of the present embodiments.

1. An electromotive machine control system for controlling an electromotive machine, comprising:
a) an electromotive machine assembly, comprising:
i) a stator element, wherein the stator element includes at least first set of a plurality of electromagnetic or permanent magnetic members arranged in a pre-defined configuration,
ii) a motion element, wherein the motion element includes at least second set of a plurality of electromagnetic or permanent magnetic members arranged in a pre-defined configuration, and
iii) an air-gap between the stator and the motion element to allow the magnetic flux to pass through;
b) a plurality of magnetic flux sensors, wherein the plurality of magnetic flux sensors positioned in the air-gap to continuously monitor magnetic flux behaviour to determine magnitude and phase angle of the magnetic flux density or one or more other parameters associated with the magnetic flux in real-time to compute sensed data;
c) a sensing unit, wherein the sensing unit analyzes magnitude and phase angle of the magnetic flux density and the one or more other parameters and further transmitting the signals to a processor for decision-making;
d) a processing unit, wherein the processing unit including:
i) a memory to store executable instructions for controlling the electromotive machine;
ii) a processor executing the stored instructions, receiving signals to generate processed signals aimed at achieving minimal energy consumption while maintaining the required operation of the electromotive machine according to user-defined parameters;
e) an electromotive machine control unit, wherein the electromotive machine control unit receives the processed signals from the processor, and regulating current flow in one or more electromagnetic members based on the processed signals by activating or deactivating one or more switches to control the electromotive machine.

2. The electromotive machine control system in accordance with claim 1, wherein the one or more parameters include but are not limited to polarity of the magnetic flux, direction of the magnetic flux, switching frequency or duty cycle.

3. The electromotive machine control system in accordance with claim 1, wherein the number of user-defined parameters comprises, but are not limited to, speed of a motion element, direction of the motion element, torque applied, accelerating time, temperature, machine current, machine voltage, active power, reactive power, input electrical characteristics, frequency, dynamic parameters, and application-specific parameters.

4. The electromotive machine control system in accordance with claim 1, wherein the electromotive machine control unit either activates or manipulates at least one of the plurality of electromagnetic members for regulating the flow of current and allows fine tuning of the electromotive machine operation.

5. The electromotive machine control system in accordance with claim 1, wherein the plurality of magnetic flux sensors provides a feedback to the processor to make instantaneous decisions for deciding magnitude and timing of the electric current to be supplied to energize atleast one of the plurality of electromagnetic member of the electromotive machine for optimum energy saving operation of the electromotive machine.

6. The electromotive machine control system in accordance with claim 1, wherein the processor makes instantaneous decisions to energize at least one of the one or more electromagnetic members in real-time based on the magnetic flux density and one or more sensed magnetic parameters by adjusting the switching frequency and the duty cycle to accomplish a desired speed and a torque of the motion element.

7. The electromotive machine control system in accordance with claim 1, wherein the processing unit dynamically generates a series of ON-OFF pulses to control the electromotive machine, aiming to achieve the objective of minimum energy usage while maintaining optimal motor operation and ensuring the magnetic flux remains at the optimum level.

8. The electromotive machine control system in accordance with claim 1, wherein the electromotive machine control unit comprises a pre-driver and protection circuit designed to ensure precise control and protect the switching devices of the electromotive machine control system, thereby enabling the electromotive machine control unit to activate or deactivate at least one pair of the plurality of electronic switches.

9. The electromotive machine control system in accordance with claim 1, wherein the electromotive machine control unit comprises a back EMF control module that includes capacitors designed to store energy from back EMF when the supply to the electromagnetic members is switched off.

10. The electromotive machinecontrol system in accordance with claim 1, wherein the plurality of magnetic flux sensors is positioned within an air-gap between the magnetic members of the stator and motion elements.

11. The electromotive machinecontrol system in accordance with claim 1, wherein the plurality of magnetic flux sensors is arranged in form of arrays and mounted on a PCB, further wherein the PCB is positioned within the air-gap between the magnetic members of the stator and motion elements.

12. The electromotive machine control system in accordance with claim 1, wherein the plurality of magnetic flux sensors is arranged at an angle with respect to the air-gap between the magnetic members of the stator and motion elements.

13. The electromotive machine control system in accordance with claim 1, wherein the plurality of semiconductor-based switches includes, but are not limited to, Bipolar Junction Transistors (BJT), Field-Effect Transistors (FET), Junction Field-Effect Transistors (JFET), Metal-Oxide-Semiconductor Field-Effect Transistors (MOSFET), Insulated-Gate Bipolar Transistors (IGBT), or Gallium nitride (GaN) transistors.

14. The electromotive machine control system in accordance with claim 1, wherein the processing unit receives one or more user-specified parameters comprises, but are not limited to, speed of a motion element, direction of the motion element, torque applied, accelerating time, temperature, machine current, machine voltage, active power, reactive power, input electrical characteristics, frequency, magnetic flux parameters, dynamic parameters, and application-specific parameters, and load characteristics, and stores the one or more user-specified parameters in the memory unit.

15. The electromotive machine in accordance with claim 1, wherein the electromotive machine encompasses a variety of configurations including, but not limited to, motors such as BLDC motors, switched reluctance motors, brushed DC motors, synchronous motors, permanent magnet synchronous motors (PMSM) and induction motors, as well as generators and linear motors.

16. The electromotive machine in accordance with claim 1, wherein the processor is an AI-based processor capable of predictive analysis using accumulated data.

17. Themagnetic members in accordance with claim 1, wherein the electromagnetic members comprise an electrical conductor in the form of a coil wound around a magnetic core, while the permanent magnetic members consist of permanent magnets.

18. A motor control system for controlling operations of a motor, wherein the motor control system:
a) a motor assembly, comprising:
i) a stator, wherein the stator includes at least first set of a plurality of electromagnetic or permanent magnetic members arranged in a pre-defined configuration,
ii) a rotor, wherein the rotor includes at least second set of a plurality of electromagnetic or permanent magnetic members arranged in a pre-defined configuration, and
iii) an air-gap between the stator and rotor allowing magnetic flux to pass through;
b) a plurality of magnetic flux sensors positioned in the air-gap or around the magnetic members, continuously monitoring magnetic flux behaviour to determine magnitude and phase angle of the magnetic flux density or one or more other parameters associated with the magnetic flux in real-time; wherein the plurality of magnetic flux sensors are arranged in form of arrays and mounted on a Printed Circuit Board (PCB), further wherein the PCB is positioned within an air gap between a rotor and a stator of the motor;
c) a sensing unit, wherein the sensing unit analyzes magnitude of the magnetic flux density and the one or more parameters to compute sensed data, and further transmitting the sensed data in form of signals to a processor for decision-making;
d) a processing unit, wherein the processing unit including:
i) a memory to store executable instructions for controlling the electromotive machine;
ii) a processor executing the stored instructions, receiving the signals to generate processed signals aimed at achieving minimal energy consumption while maintaining required motor operation;
e) an electromotive machine control unit receiving processed signals from the processor, and further regulating current flow in one or more electromagnetic members based on processed signals by activating or deactivating one or more switches to control the motor.

19. A method for controlling operations of an electromotive machine, wherein the method comprising:
a. arranging a plurality of magnetic flux sensors in the vicinity of a plurality of magnetic coils;
b. acquiring one or more user-specified operating parameters of an electromotive machine from a user;
c. storing the one or more user-specified operating parameters in a memory;
d. initiating operation of an electromotive machine based on the one or more user-specified parameters;
e. detecting a plurality of parameters related to magnetic flux behaviour using a plurality of magnetic flux sensors;
f. analyzing values of the plurality of parameters related to the magnetic flux behaviour in real-time; and
g. regulating the flow of electrical current within the plurality of magnetic members by selectively activating or deactivating at least one pair of a plurality of electronic switches to control operations of the electromotive machine in minimum energy usage mode.

20. The method in accordance with claim 19, wherein the plurality of parameters are selected from a magnitude, a density or a phase angle of the magnetic flux behaviour.
